(19) United States
(12) Patent Application Publication
(10) Pub. No.: US 2025/0105588 A1
(43) Pub. Date: Mar. 27, 2025

(54) SEMICONDUCTOR LIGHT EMITTING DEVICE

(71) Applicant: ROHM CO., LTD., Kyoto (JP)

(72) Inventor: Yotaro HIGASE, Kyoto (JP)

(73) Assignee: ROHM CO., LTD., Kyoto (JP)

(21) Appl. No.: 18/798,382

(22) Filed: Aug. 8, 2024

(30) Foreign Application Priority Data
Sep. 25, 2023 (JP) 2023-160330

(51) Int. Cl. H01S 5/042; H01S 5/22; H01S 5/34; H01S 5/343

(52) U.S. Cl. CPC H01S 5/04256; H01S 5/22; H01S 5/3416; H01S 5/34313; H01S 5/34353

(57) ABSTRACT

A semiconductor light emitting device comprises a current confinement layer and a semiconductor light emitting stack. The semiconductor light emitting stack is disposed on the current confinement layer and has a bottom surface in contact with the current confinement layer. The current confinement layer includes an insulating layer and a plurality of conductive portions. The plurality of conductive portions are disposed in the insulating layer in contact with the bottom surface. An area ratio of the plurality of conductive portions to the bottom surface is 7% or more and 15% or less.

### CROSS REFERENCE TO RELATED APPLICATIONS

This nonprovisional application is based on Japanese Patent Application No. 2023-160330 filed on Sep. 25, 2023 with the Japan Patent Office, the entire contents of which are hereby incorporated by reference.

### BACKGROUND OF THE INVENTION

### Field of the Invention

The present disclosure relates to a semiconductor light emitting device.

### Description of the Background Art

Japanese Patent Laying-Open No. 2020-065041 discloses a semiconductor light emitting device.

### BRIEF DESCRIPTION OF THE DRAWINGS

FIG. 1 is a schematic plan view of a semiconductor light emitting device according to an embodiment.

FIG. 2 is a schematic cross section of the semiconductor light emitting device according to the embodiment taken along a cross-sectional line II-II indicated in FIG. 1.

FIG. 3 is a schematic cross section showing one step of a method for manufacturing the semiconductor light emitting device according to the embodiment.

FIG. 4 is a schematic partial enlarged cross section showing a step following the step shown in FIG. 3 in the method for manufacturing the semiconductor light emitting device according to the embodiment.

FIG. 5 is a schematic partial enlarged cross section showing a step following the step shown in FIG. 4 in the method for manufacturing the semiconductor light emitting device according to the embodiment.

FIG. 6 is a schematic partial enlarged cross section showing a step following the step shown in FIG. 5 in the method for manufacturing the semiconductor light emitting device according to the embodiment.

FIG. 7 is a schematic partial enlarged cross section showing a step following the step shown in FIG. 6 in the method for manufacturing the semiconductor light emitting device according to the embodiment.

FIG. 8 is a schematic partial enlarged cross section showing a step following the step shown in FIG. 7 in the method for manufacturing the semiconductor light emitting device according to the embodiment.

FIG. 9 is a schematic partial enlarged cross section showing a step following the step shown in FIG. 8 in the method for manufacturing the semiconductor light emitting device according to the embodiment.

FIG. 10 is a schematic partial enlarged cross section showing a step following the step shown in FIG. 9 in the method for manufacturing the semiconductor light emitting device according to the embodiment.

FIG. 11 is a schematic partial enlarged cross section showing a step following the step shown in FIG. 10 in the method for manufacturing the semiconductor light emitting device according to the embodiment.

FIG. 12 is a graph representing a relationship between an area ratio of a plurality of conductive portions to a bottom surface of a semiconductor light emitting stack and optical output of the semiconductor light emitting device.

FIG. 13 is a graph representing a relationship between carrier concentration of a p-type contact layer and forward voltage of the semiconductor light emitting device.

FIG. 14 is a schematic plan view of a semiconductor light emitting device according to a first variation of the embodiment.

FIG. 15 is a schematic plan view of a semiconductor light emitting device according to a second variation of the embodiment.

FIG. 16 is a schematic plan view of a semiconductor light emitting device according to a third variation of the embodiment.

### DETAILED DESCRIPTION

An embodiment of the present disclosure will now be described in detail with reference to the drawings. In the figures referred to below, identical or equivalent components are identically denoted and will not be described repeatedly. At least portions in configuration of the embodiment described below may be combined together as desired.

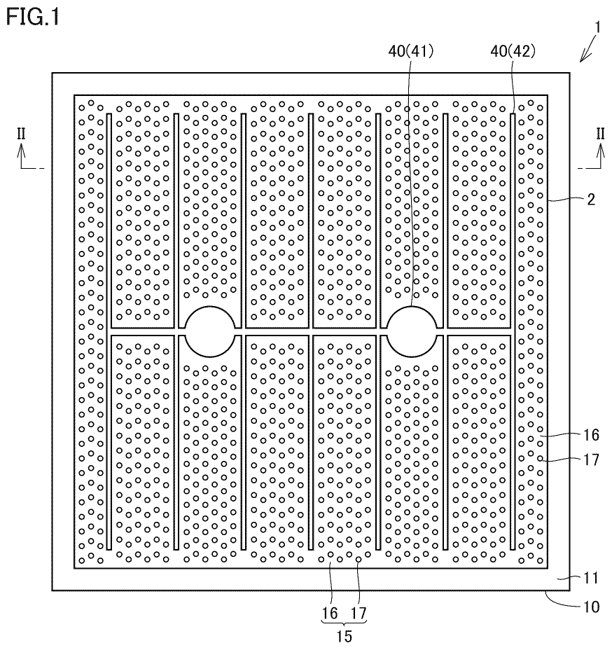

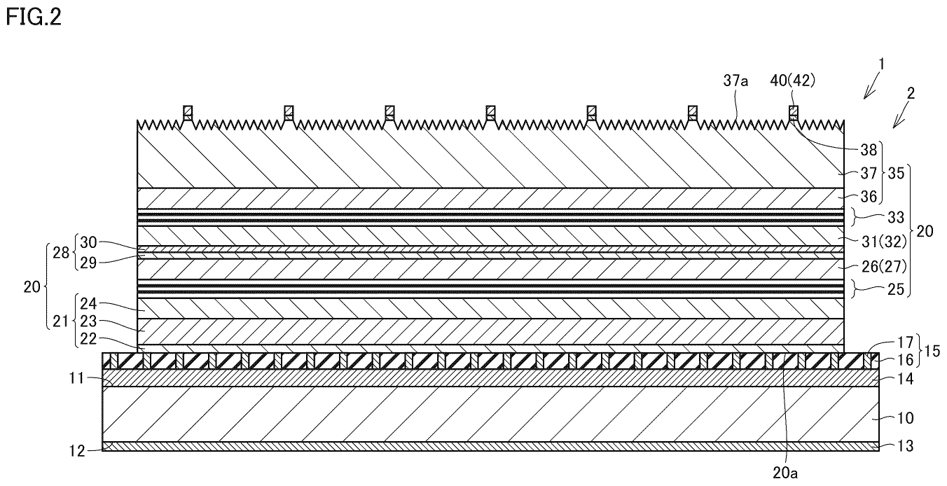

A semiconductor light emitting device 1 according to an embodiment will now be described with reference to FIGS. 1 and 2. Semiconductor light emitting device 1 is for example a light emitting diode (LED). Semiconductor light emitting device 1 comprises a substrate 10, an anode electrode 13, a reflective layer 14, a current confinement layer 15, a semiconductor light emitting stack 20, and a cathode electrode 40.

Substrate 10 includes a major surface 11 and a major surface 12 opposite to major surface 11. Substrate 10 is for example a semiconductor substrate such as a p⁺⁺-type silicon (Si) substrate, or a conductor substrate such as a metal substrate including at least one of aluminum (Al), copper (Cu), gold (Au), or silver (Ag).

Reflective layer 14 is disposed on substrate 10 at major surface 11. Reflective layer 14 is disposed on a surface of current confinement layer 15 facing away from semiconductor light emitting stack 20. Reflective layer 14 reflects light emitted from semiconductor light emitting stack 20. Reflective layer 14 has a thickness for example of 0.1 μm or more and 3.0 μm or less. Reflective layer 14 is formed for example of Au or an Au-containing alloy. Reflective layer 14 may be a single layer of Au, a single layer of an Au alloy, a stack of an Au layer and another metal layer, or a stack of an Au alloy layer and another metal layer. When reflective layer 14 is a stack of layers, an outermost surface of reflective layer 14 in contact with semiconductor light emitting stack 20 is preferably formed of an Au layer or an Au alloy layer (e.g., a gold-beryllium-nickel (AuBeNi) alloy). When reflective layer 14 is a stack of layers, reflective layer 14 is for example a stack of Au/Ti with the Au closer to current confinement layer 15 and the Ti closer to substrate 10.

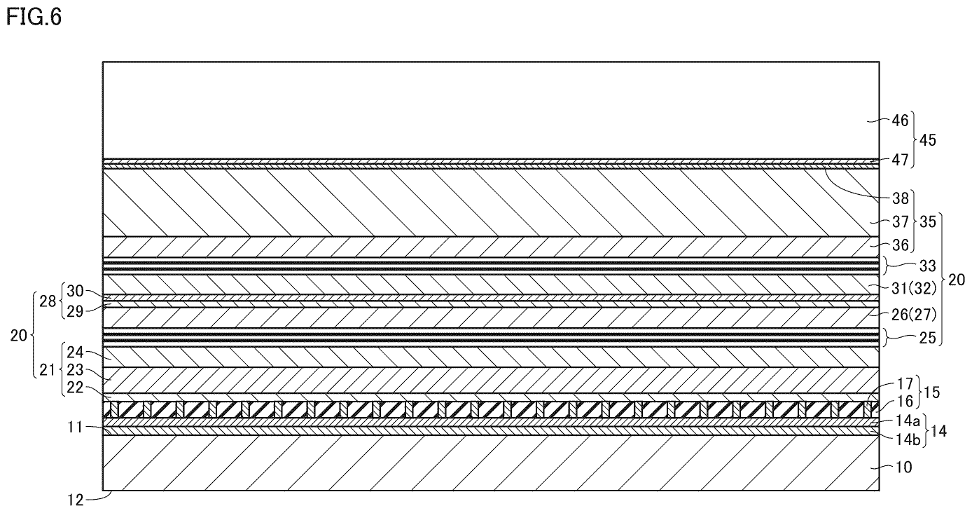

Reflective layer 14 may be formed by joining a growth substrate 45 (see FIG. 6) and substrate 10 together and bonding a first metal layer 14a (see FIG. 6) and a second metal layer 14b (see FIG. 6) together. Therefore, reflective layer 14 may have a boundary of first and second metal layers 14a and 14b (or their joined surfaces). When reflective layer 14 is formed of a plurality of metal materials, the plurality of metal materials may not have a clear boundary formed therebetween and may instead have a composition gradually changing in the direction of the thickness of reflective layer 14.

Current confinement layer 15 is disposed on reflective layer 14. Current confinement layer 15 includes an insulating layer 16 and a plurality of conductive portions 17. Insulating layer 16 is formed for example of silicon dioxide (SiO₂).

The plurality of conductive portions 17 are disposed in insulating layer 16. Specifically, the plurality of conductive portions 17 are formed in a plurality of through holes formed in insulating layer 16. The plurality of conductive portions 17 are for example a plurality of conductive pillars. The plurality of conductive portions 17 are in contact with reflective layer 14 and a bottom surface 20a of semiconductor light emitting stack 20 and electrically interconnect reflective layer 14 and semiconductor light emitting stack 20. Specifically, the plurality of conductive portions 17 are in contact with reflective layer 14 and a p-type contact layer 22 and electrically interconnect reflective layer 14 and p-type contact layer 22. In a plan view of major surface 11, the plurality of conductive portions 17 each have a diameter for example of 5 μm or more and 15 μm or less. In the plan view of major surface 11, the plurality of conductive portions 17 may be disposed uniformly.

The plurality of conductive portions 17 are formed for example of a metal material such as Au or an alloy such as a gold-beryllium (AuBe) alloy. When a semiconductor light emitting layer (a first semiconductor light emitting layer 25 and a second semiconductor light emitting layer 33) emits light having a wavelength of 800 nm or more and 1000 nm or less, the plurality of conductive portions 17 made of Au have a higher reflectance than the plurality of conductive portions 17 made of AuBe for the light emitted from the semiconductor light emitting layer. Therefore, the plurality of conductive portions 17 made of Au increase optical output of semiconductor light emitting device 1.

Semiconductor light emitting stack 20 includes bottom surface 20a in contact with current confinement layer 15. Semiconductor light emitting stack 20 may be formed into a mesa structure 2. Semiconductor light emitting stack 20 includes a first p-type layer 21, first semiconductor light emitting layer 25, a first n-type layer 26, a tunnel diode layer 28, a second p-type layer 31, second semiconductor light emitting layer 33, and a second n-type layer 35.

First p-type layer 21 is disposed on current confinement layer 15. First p-type layer 21 includes a p-type contact layer 22, a p-type window layer 23, and a first p-type cladding layer 24.

P-type contact layer 22 is disposed on current confinement layer 15. P-type contact layer 22 is a low-resistance layer for making ohmic contact with the plurality of conductive portions 17. P-type contact layer 22 is for example a layer having the highest p-type dopant concentration or carrier concentration (or hole concentration) in first p-type layer 21. P-type contact layer 22 is for example an AlGaAsP layer doped with a p-type dopant such as carbon (C) or a GaP layer doped with a p-type dopant such as zinc (Zn). P-type contact layer 22 has a carrier concentration (or a hole concentration) for example of 1×10¹⁹ cm⁻³ or more. P-type contact layer 22 may have a carrier concentration (or a hole concentration) of 2×10¹⁹ cm⁻³ or more or 5×10¹⁹ cm⁻³ or more.

P-type window layer 23 is disposed on p-type contact layer 22. P-type window layer 23 is for example an AlGaAs layer doped with carbon (C).

First p-type cladding layer 24 is disposed on p-type window layer 23. First p-type cladding layer 24 is for example an AlGaAs layer doped with carbon (C). First p-type cladding layer 24 has a compositional ratio of Al higher than that of Al of p-type window layer 23.

First semiconductor light emitting layer 25 is disposed on first p-type layer 21 (or first p-type cladding layer 24). First semiconductor light emitting layer 25 is a layer that emits light when a current is injected into semiconductor light emitting device 1. First semiconductor light emitting layer 25 emits light having a wavelength for example of 800 nm or more and 1000 nm or less. First semiconductor light emitting layer 25 is for example a multiple quantum well (MQW) layer. First semiconductor light emitting layer 25 is for example an MQW layer composed of an InGaAs well layer and an AlGaAsP barrier layer stacked alternately. First semiconductor light emitting layer 25 is for example an undoped layer.

First n-type layer 26 is disposed on first semiconductor light emitting layer 25. First n-type layer 26 is for example a first n-type cladding layer 27. First n-type cladding layer 27 is for example an AlGaAs layer doped with selenium (Se). First n-type cladding layer 27 has as high a compositional ratio of Al as that of Al of first p-type cladding layer 24.

Tunnel diode layer 28 is disposed between first n-type layer 26 and second p-type layer 31 and is in contact with first n-type layer 26 and second p-type layer 31. Tunnel diode layer 28 receives holes injected from anode electrode 13 and passes the holes toward second semiconductor light emitting layer 33, and also receives electrons injected from cathode electrode 40 and passes the electrons toward first semiconductor light emitting layer 25. Thus, the electrons and holes are injected into each of first and second semiconductor light emitting layers 25 and 33, and first and second semiconductor light emitting layers 25 and 33 emit light.

Tunnel diode layer 28 for example includes an n⁺⁺ tunnel layer 29 disposed on first n-type cladding layer 27 and a p⁺⁺ tunnel layer 30 disposed on n⁺⁺ tunnel layer 29. N⁺⁺ tunnel layer 29 is for example an AlGaAs layer doped with tellurium (Te). P⁺⁺ tunnel layer 30 is for example an AlGaAs layer doped with carbon (C). N⁺⁺ tunnel layer 29 and p⁺⁺ tunnel layer 30 each have as low a compositional ratio of Al as that of Al of p-type window layer 23.

Second p-type layer 31 is disposed on tunnel diode layer 28 (or p⁺⁺ tunnel layer 30). Second p-type layer 31 is for example a second p-type cladding layer 32. Second p-type cladding layer 32 is for example an AlGaAs layer doped with carbon (C). Second p-type cladding layer 32 has as high a compositional ratio of Al as that of Al of first p-type cladding layer 24.

Second semiconductor light emitting layer 33 is disposed on second p-type layer 31 (or second p-type cladding layer 32). Second semiconductor light emitting layer 33 is a layer that emits light when a current is injected into semiconductor light emitting device 1. Second semiconductor light emitting layer 33 emits light having a wavelength for example of 800 nm or more and 1000 nm or less. For example, second semiconductor light emitting layer 33 is configured in the same manner as first semiconductor light emitting layer 25 and emits light having the same wavelength as first semiconductor light emitting layer 25. Since first and second semiconductor light emitting layers 25 and 33 emit light, semiconductor light emitting device 1 provides an increased optical output. Second semiconductor light emitting layer 33 is for example a multiple quantum well (MQW) layer. Second semiconductor light emitting layer 33 is for example an MQW layer composed of an InGaAs well layer and an AlGaAsP barrier layer stacked alternately. Second semiconductor light emitting layer 33 is for example an undoped layer.

Second n-type layer 35 is disposed on second semiconductor light emitting layer 33. Second n-type layer 35 includes a second n-type cladding layer 36, an n-type window layer 37, and an n-type contact layer 38.

Second n-type cladding layer 36 is disposed on second semiconductor light emitting layer 33. Second n-type cladding layer 36 is for example an AlGaAs layer doped with selenium (Se). Second n-type cladding layer 36 has as high a compositional ratio of Al as that of Al of first n-type cladding layer 27.

N-type window layer 37 is disposed on second n-type cladding layer 36. N-type window layer 37 is for example an AlGaAs layer doped with silicon (Si). N-type window layer 37 has a compositional ratio of Al lower than that of Al of second n-type cladding layer 36. N-type window layer 37 has as low a compositional ratio of Al as that of Al of p-type window layer 23. An uneven structure 37a is formed on a surface of n-type window layer 37 at a portion exposed from n-type contact layer 38 and cathode electrode 40. Uneven structure 37a increases efficiency of extracting light from semiconductor light emitting device 1.

N-type contact layer 38 is disposed on n-type window layer 37. N-type contact layer 38 is a low-resistance layer for making ohmic contact with cathode electrode 40. N-type contact layer 38 is for example a layer having the highest n-type dopant concentration or carrier concentration (or electron concentration) in second n-type layer 35. N-type contact layer 38 is for example a GaAs layer doped with silicon (Si).

Anode electrode 13 is disposed on substrate 10 at major surface 12. Anode electrode 13 is formed for example of a metal material such as Au or an alloy containing Au. In the present embodiment, anode electrode 13 is for example a stack of Ti/Au with the Ti closer to substrate 10.

Cathode electrode 40 is formed for example of a metal material such as Au or an alloy containing Au. In the present embodiment, cathode electrode 40 is for example a stack of AuGeNi/Au with the AuGeNi closer to n-type contact layer 38. Cathode electrode 40 includes a pad electrode 41 and a branch electrode 42. In order to inject a current into semiconductor light emitting device 1, a conductive wire (not shown) is bonded to pad electrode 41. Branch electrode 42 in the plan view of major surface 11 extends in the form of a branch from pad electrode 41 so as to divide semiconductor light emitting stack 20 into a plurality of regions.

An area ratio of the plurality of conductive portions 17 to bottom surface 20a of semiconductor light emitting stack 20 is 7% or more and 15% or less. In the present specification, an area ratio of the plurality of conductive portions 17 to bottom surface 20a of semiconductor light emitting stack 20 is a ratio of an area of the plurality of conductive portions 17 overlapping bottom surface 20a of semiconductor light emitting stack 20 in the plan view of major surface 11 to a first area of bottom surface 20a of semiconductor light emitting stack 20. The plan view of major surface 11 of substrate 10 is a plan view of bottom surface 20a of semiconductor light emitting stack 20.

An example of a method for manufacturing semiconductor light emitting device 1 of the present embodiment will now be described with reference to FIGS. 2 to 11.

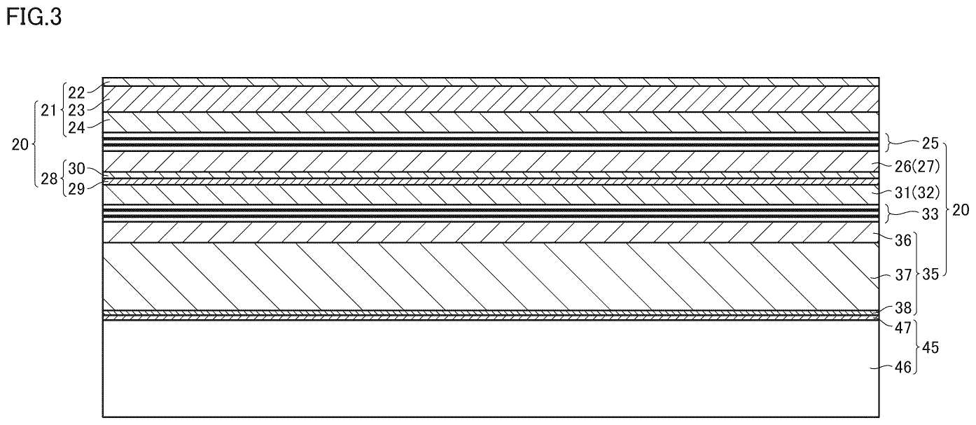

Referring to FIG. 3, semiconductor light emitting stack 20 is formed on growth substrate 45. Growth substrate 45 includes a support substrate 46 and an etching stopper layer 47. Support substrate 46 is formed for example of GaAs. Etching stopper layer 47 is disposed on support substrate 46. Etching stopper layer 47 is formed for example of AlInGaP. Etching stopper layer 47 is formed on support substrate 46 by an epitaxial growth method such as metal organic chemical vapor deposition (MOCVD) or molecular beam epitaxy (MBE).

Semiconductor light emitting stack 20 is formed on growth substrate 45 (or etching stopper layer 47) by an epitaxial growth method such as metal organic chemical vapor deposition (MOCVD) or molecular beam epitaxy (MBE). N-type contact layer 38, n-type window layer 37, second n-type cladding layer 36, second semiconductor light emitting layer 33, second p-type cladding layer 32, p⁺⁺ tunnel layer 30, n⁺⁺ tunnel layer 29, first n-type cladding layer 27, first semiconductor light emitting layer 25, first p-type cladding layer 24, p-type window layer 23, and p-type contact layer 22 are stacked in this order successively on the side of growth substrate 45 to form semiconductor light emitting stack 20.

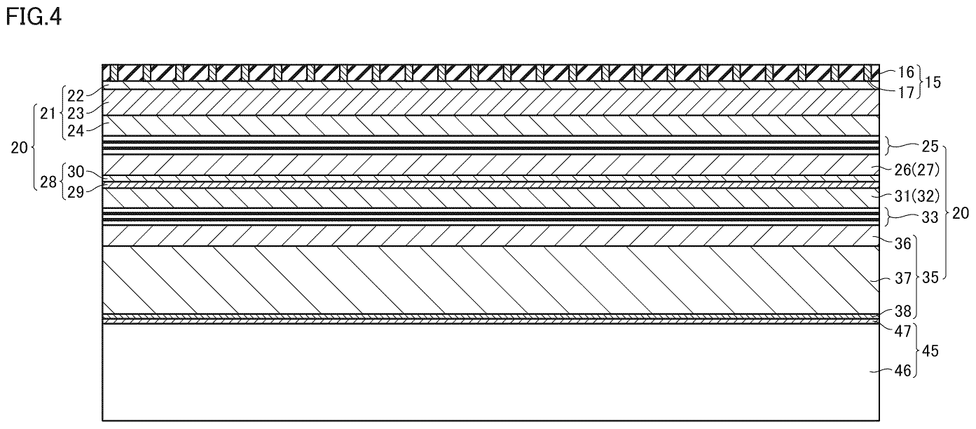

Referring to FIG. 4, current confinement layer 15 is formed on p-type contact layer 22. Specifically, insulating layer 16 is formed on p-type contact layer 22 by chemical vapor deposition (CVD). Insulating layer 16 is partially etched to form a plurality of through holes in insulating layer 16. The plurality of conductive portions 17 are formed in the plurality of through holes by vapor deposition. Current confinement layer 15 is thus formed.

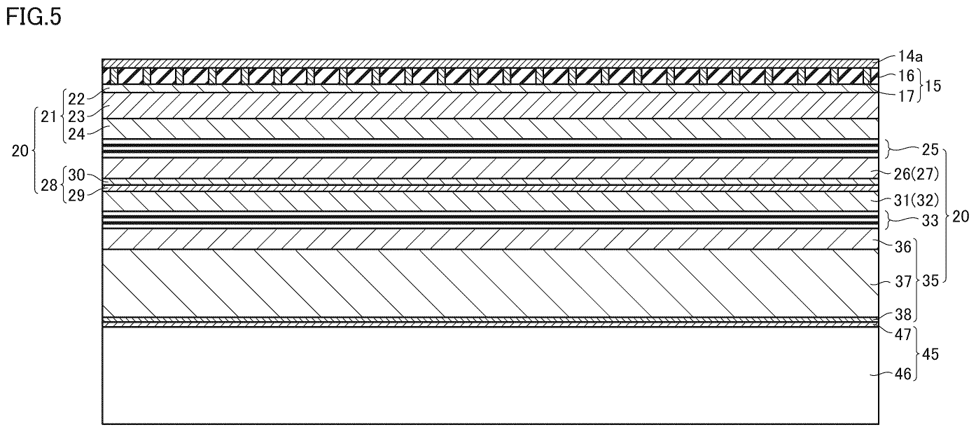

Referring to FIG. 5, first metal layer 14a is formed on current confinement layer 15 by vapor deposition. First metal layer 14a is formed of Au or an Au-containing alloy. At least an outermost surface of first metal layer 14a is formed of Au. Thus, a stack including semiconductor light emitting stack 20, current confinement layer 15, and first metal layer 14a is formed on growth substrate 45.

Referring to FIG. 6, substrate 10 is joined to the stack formed on growth substrate 45. Specifically, second metal layer 14b is formed on substrate 10 at major surface 11 by vapor deposition. Second metal layer 14b is formed of Au or an Au-containing alloy. At least an outermost surface of second metal layer 14b is formed of Au. Subsequently, first and second metal layers 14a and 14b are bonded together. First and second metal layers 14a and 14b are bonded together for example by thermocompression bonding. First and second metal layers 14a and 14b are bonded together to form reflective layer 14.

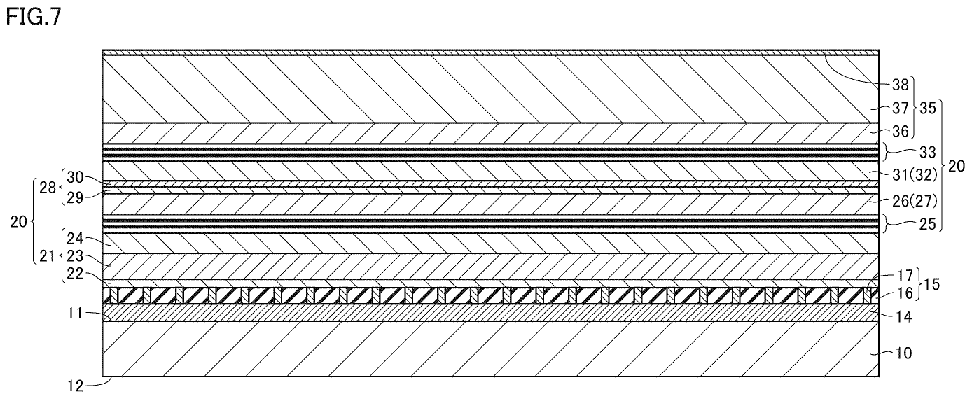

Referring to FIG. 7, growth substrate 45 is removed. Specifically, support substrate 46 is removed by wet etching. Etching stopper layer 47 is substantially not etched away with respect to this wet etching, and functions as an etching stopper layer with respect to the wet etching. Subsequently, etching stopper layer 47 is removed by another etching. Growth substrate 45 is thus removed.

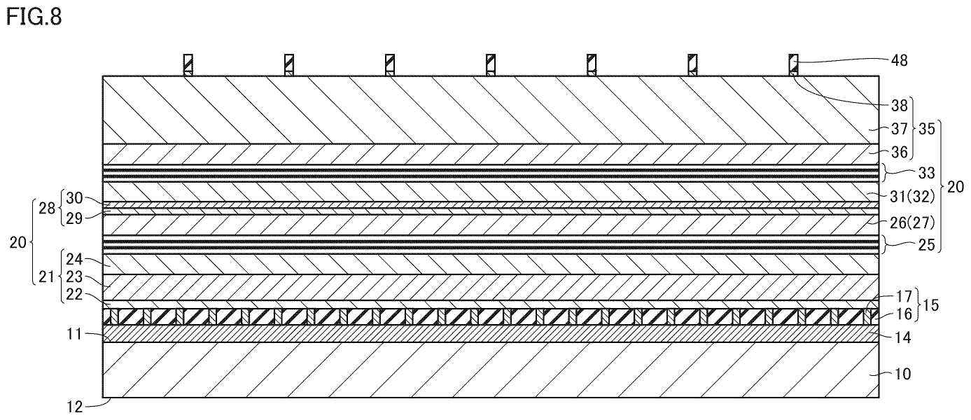

Referring to FIG. 8, n-type contact layer 38 is patterned. Specifically, a resist 48 is formed on n-type contact layer 38. Resist 48 for example has the same pattern as cathode electrode 40. Subsequently, n-type contact layer 38 is etched using resist 48 as a mask. A portion of n-type contact layer 38 exposed from resist 48 is removed to form n-type contact layer 38 having the same pattern as cathode electrode 40. N-type window layer 37 is exposed from resist 48 and n-type contact layer 38 through an opening of resist 48 and an opening of n-type contact layer 38.

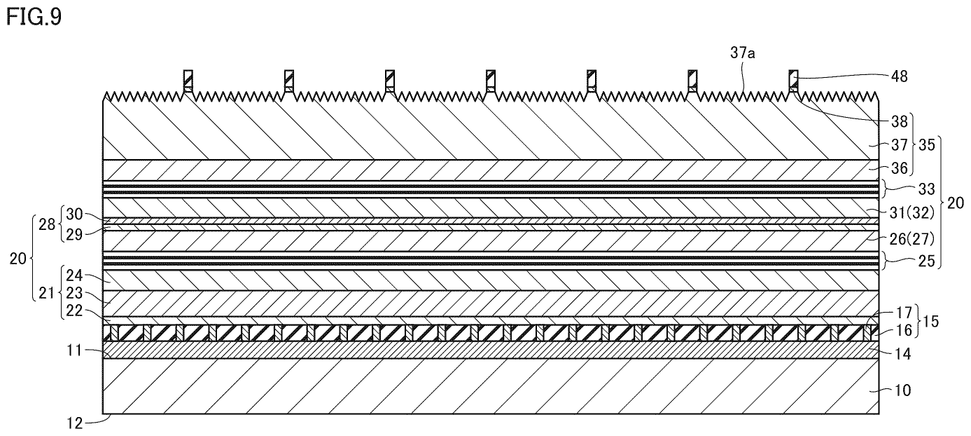

Referring to FIG. 9, a surface of n-type window layer 37 exposed from resist 48 is for example frosted to form uneven structure 37a on the surface. The frosting may be done by wet etching or dry etching.

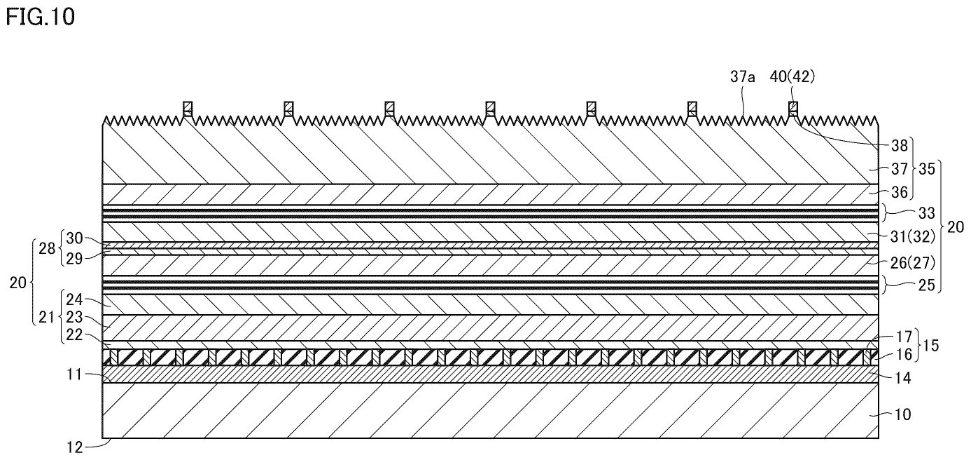

Referring to FIG. 10, resist 48 is removed. Cathode electrode 40 is formed on n-type contact layer 38. Cathode electrode 40 is formed for example by vapor deposition of a metal layer and removal of a portion of the metal layer by lift-off.

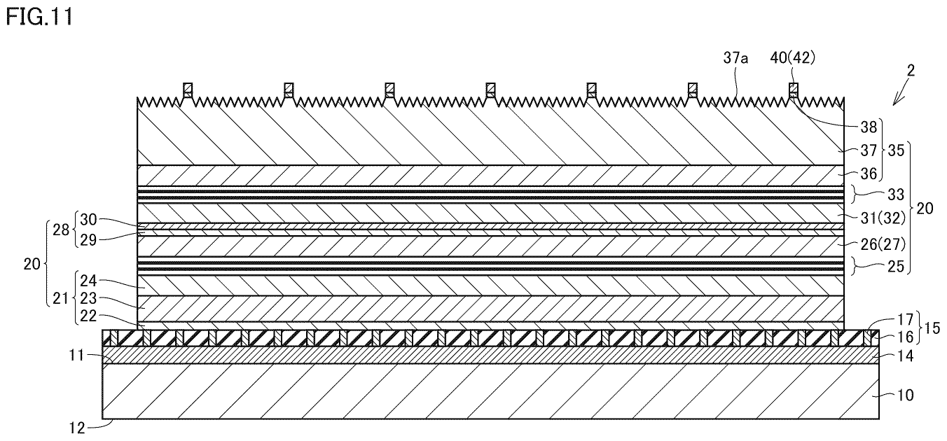

Referring to FIG. 11, semiconductor light emitting stack 20 is formed into mesa structure 2. Mesa structure 2 is formed for example by wet etching a side surface of semiconductor light emitting stack 20. Subsequently, anode electrode 13 is formed on substrate 10 at major surface 12 for example by vapor deposition. Semiconductor light emitting device 1 is thus obtained.

An operation of semiconductor light emitting device 1 of the present embodiment will now be described.

A voltage higher than that of cathode electrode 40 is applied to anode electrode 13 to apply a forward bias voltage V_{f} to semiconductor light emitting device 1. A forward current I_{f} flows from anode electrode 13 to cathode electrode 40. In the present embodiment, forward current I_{f} is a high current of 3 amperes or more, and semiconductor light emitting device 1 provides a high optical output of 1 W or more. Holes are injected into semiconductor light emitting device 1 from anode electrode 13 through substrate 10, reflective layer 14, and the plurality of conductive portions 17. Electrons are injected into semiconductor light emitting device 1 from cathode electrode 40. The electrons and holes tunnel through tunnel diode layer 28. Therefore, carriers (electrons and holes) are injected into first and second semiconductor light emitting layers 25 and 33.

The electrons and holes are combined in first and second semiconductor light emitting layers 25 and 33, and first and second semiconductor light emitting layers 25 and 33 emit light. The light emitted from first and second semiconductor light emitting layers 25 and 33 is reflected by reflective layer 14 and the plurality of conductive portions 17. The light emitted from first and second semiconductor light emitting layers 25 and 33 is extracted out of semiconductor light emitting device 1 by uneven structure 37a or the like. In this way, semiconductor light emitting device 1 emits light.

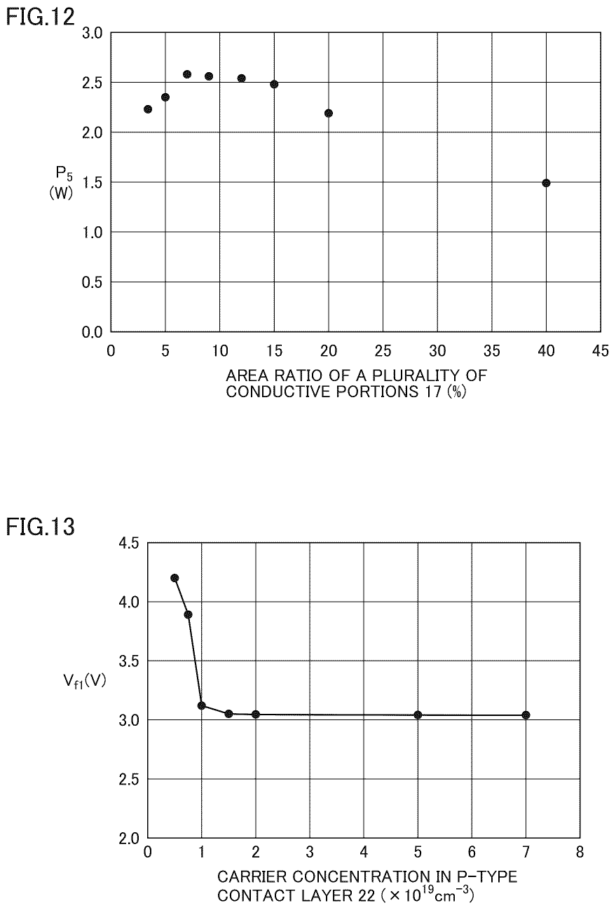

A function of semiconductor light emitting device 1 of the present embodiment will now be described with reference to a result of a sample of semiconductor light emitting device 1 as shown in FIGS. 12 and 13. The sample of semiconductor light emitting device 1 comprises reflective layer 14 formed of Au and p-type contact layer 22 formed of AlGaAsP doped with carbon (C). In the above sample, the plurality of conductive portions 17 each have a diameter of 10 μm, bottom surface 20a of semiconductor light emitting stack 20 has a size of 1020 μm×1020 μm in the plan view of major surface 11, and first and second semiconductor light emitting layers 25 and 33 emit light having a wavelength of 940 nm.

FIG. 12 is a graph representing a relationship between an area ratio of the plurality of conductive portions 17 to bottom surface 20a of semiconductor light emitting stack 20 and an optical output of semiconductor light emitting device 1. The optical output of semiconductor light emitting device 1 represented in FIG. 12 is an optical output P₅ of semiconductor light emitting device 1 when forward current I_{f} of 5 amperes is injected into semiconductor light emitting device 1.

As shown in FIG. 12, optical output P₅ of semiconductor light emitting device 1 when the above area ratio is less than 7% is lower than optical output P₅ of semiconductor light emitting device 1 when the above area ratio is 7% or more and 15% or less. A reason for this is as follows.

Holes pass through current confinement layer 15 via the plurality of conductive portions 17 rather than insulating layer 16. Therefore, when the above area ratio is less than 7%, the holes locally concentrate in semiconductor light emitting stack 20. When a high current such as 5 amperes is injected into semiconductor light emitting device 1, non-radiative recombination of carriers (electrons and holes) occurs more, and semiconductor light emitting device 1 has reduced luminous efficacy. That is, when the above area ratio is less than 7%, a drooping effect occurs. In contrast, when the above area ratio is 7% or more, local concentration of holes in semiconductor light emitting stack 20 is alleviated. Therefore, even when a high current such as 5 amperes is injected into semiconductor light emitting device 1, non-radiative recombination of carriers is suppressed, and semiconductor light emitting device 1 has increased luminous efficacy. That is, when the above area ratio is 7% or more, the drooping effect is suppressed.

As shown in FIG. 12, optical output P₅ of semiconductor light emitting device 1 when the above area ratio is larger than 15% is lower than optical output P₅ of semiconductor light emitting device 1 when the above area ratio is 7% or more and 15% or less. This is because when the above area ratio is larger than 15%, semiconductor light emitting stack 20 internally has an excessively low current density and semiconductor light emitting device 1 has reduced luminous efficacy.

FIG. 13 is a graph representing a relationship between carrier concentration (or hole concentration) of p-type contact layer 22 and forward voltage V_{f} of semiconductor light emitting device 1. P-type contact layer 22 has a carrier concentration adjusted by an amount of carbon (C) used to dope p-type contact layer 22 formed of AlGaAsP. Forward voltage V_{f} of semiconductor light emitting device 1 represented in FIG. 13 is a forward voltage V_{f1} of semiconductor light emitting device 1 when forward current I_{f} of 1 ampere is injected into semiconductor light emitting device 1.

As represented in FIG. 13, when p-type contact layer 22 has a carrier concentration of 1.0×10¹⁹ cm⁻³ or more, the plurality of conductive portions 17 and p-type contact layer 22 have an improved ohmic contact therebetween, and accordingly, semiconductor light emitting device 1 has low forward voltage V_{f}. For example, when p-type contact layer 22 is formed of AlGaAsP doped with carbon (C), p-type contact layer 22 made of AlGaAsP can be doped with more carbon (C), and p-type contact layer 22 can easily have a carrier concentration of 1.0×10¹⁹ cm⁻³ or more.

In contrast, when p-type contact layer 22 has a carrier concentration of less than 1.0×10¹⁹ cm⁻³, the plurality of conductive portions 17 and p-type contact layer 22 have an insufficient ohmic contact therebetween, and semiconductor light emitting device 1 has increased forward voltage V_{f}. For example, when p-type contact layer 22 is formed of GaP doped with zinc (Zn), p-type contact layer 22 would have a carrier concentration of less than 1.0×10¹⁹ cm⁻³.

A variation of the present embodiment will now be described.

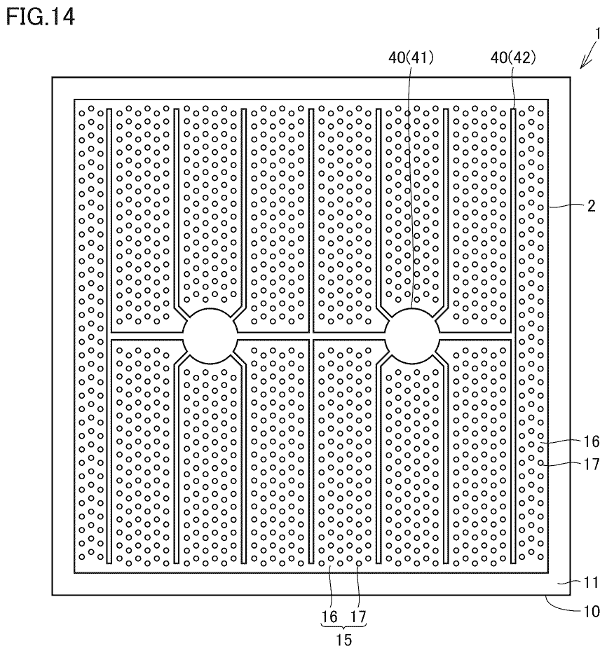

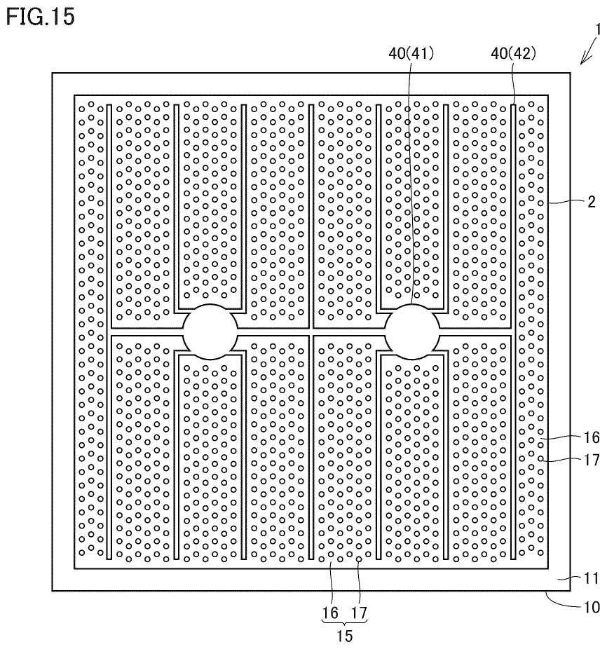

How branch electrode 42 is arranged is not limited to how branch electrode 42 is arranged as shown in FIG. 1. For example, branch electrode 42 may be arranged as shown in FIG. 14 or 15.

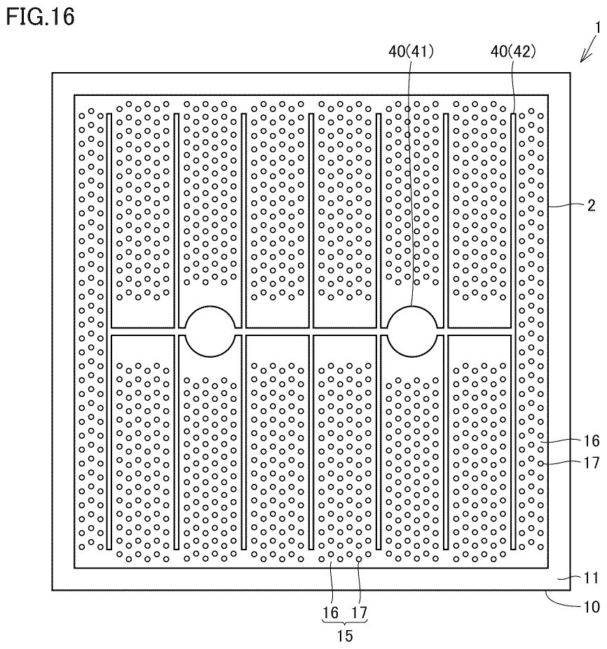

As shown in FIG. 16, the plurality of conductive portions 17 may be unevenly disposed in the plan view of major surface 11. For example, as shown in FIG. 16, a first area ratio of the plurality of conductive portions 17 at a central portion of semiconductor light emitting stack 20 may be smaller than a second area ratio of the plurality of conductive portions 17 at a peripheral portion of semiconductor light emitting stack 20. The first area ratio is a ratio of an area of the plurality of conductive portions 17 overlapping the central portion of semiconductor light emitting stack 20 in the plan view of major surface 11 to the area of the central portion of semiconductor light emitting stack 20. The second area ratio is a ratio of an area of the plurality of conductive portions 17 overlapping the peripheral portion of semiconductor light emitting stack 20 in the plan view of major surface 11 to the area of the peripheral portion of semiconductor light emitting stack 20.

While semiconductor light emitting device 1 comprises two semiconductor light emitting layers (first and second semiconductor light emitting layers 25 and 33), it may comprise a single semiconductor light emitting layer or may comprise three or more semiconductor light emitting layers. Semiconductor light emitting device 1 may be a laser diode (LD).

Effects of semiconductor light emitting device 1 of the present embodiment will now be described.

Semiconductor light emitting device 1 of the present disclosure comprises current confinement layer 15 and semiconductor light emitting stack 20. Semiconductor light emitting stack 20 is disposed on current confinement layer 15 and has bottom surface 20a in contact with current confinement layer 15. Current confinement layer 15 includes insulating layer 16 and the plurality of conductive portions 17. The plurality of conductive portions 17 are disposed in insulating layer 16 in contact with bottom surface 20a. An area ratio of the plurality of conductive portions 17 to bottom surface 20a is 7% or more and 15% or less. The above area ratio is a ratio to the first area of bottom surface 20a of the second area of the plurality of conductive portions 17 overlapping bottom surface 20a in the plan view of bottom surface 20a.

The above area ratio of 7% or more alleviates local concentration of holes in semiconductor light emitting stack 20. Even when a high current is injected into semiconductor light emitting device 1, non-radiative recombination of carriers (or electrons and holes) is suppressed, and semiconductor light emitting device 1 has increased luminous efficacy. That is, the above area ratio of 7% or more suppresses the drooping effect. Furthermore, the above area ratio of 15% or less prevents semiconductor light emitting stack 20 from internally having an excessively low current density. Semiconductor light emitting device 1 has increased luminous efficacy. Semiconductor light emitting device 1 thus provides an increased optical output when a high current is injected thereto.

In semiconductor light emitting device 1 of the present embodiment, the plurality of conductive portions 17 are formed of gold (Au).

This increases reflectance of the plurality of conductive portions 17 with respect to light emitted from a semiconductor light emitting layer (first semiconductor light emitting layer 25). The light is reflected by the plurality of conductive portions 17 and emitted out of semiconductor light emitting device 1 without being absorbed by substrate 10. Semiconductor light emitting device 1 provides an increased optical output.

In semiconductor light emitting device 1 of the present embodiment, semiconductor light emitting stack 20 includes p-type contact layer 22 in contact with the plurality of conductive portions 17. P-type contact layer 22 has a carrier concentration of 1×10¹⁹ cm⁻³ or more.

This improves ohmic contact between the plurality of conductive portions 17 and p-type contact layer 22. Semiconductor light emitting device 1 has reduced forward voltage V_{f}.

In semiconductor light emitting device 1 of the present embodiment, p-type contact layer 22 is formed of p-AlGaAsP doped with a p-type dopant.

This can facilitate increasing a carrier concentration of p-type contact layer 22 to 1×10¹⁹ cm⁻³ or more. Ohmic contact between the plurality of conductive portions 17 and p-type contact layer 22 is improved. Semiconductor light emitting device 1 has reduced forward voltage V_{f}.

Semiconductor light emitting device 1 of the present embodiment further comprises reflective layer 14 disposed on a surface of current confinement layer 15 facing away from semiconductor light emitting stack 20. The plurality of conductive portions 17 are in contact with reflective layer 14.

Light emitted from semiconductor light emitting stack 20 is reflected by reflective layer 14, and the light is emitted out of semiconductor light emitting device 1 without being absorbed by substrate 10. Semiconductor light emitting device 1 provides an increased optical output.

In semiconductor light emitting device 1 of the present embodiment, the plurality of conductive portions 17 are disposed uniformly in the plan view of bottom surface 20a.

Therefore, semiconductor light emitting device 1 can uniformly emit light. Semiconductor light emitting device 1 provides an increased optical output.

In semiconductor light emitting device 1 of the present embodiment, the first area ratio of the plurality of conductive portions 17 at the central portion of semiconductor light emitting stack 20 is smaller than the second area ratio of the plurality of conductive portions 17 at the peripheral portion of semiconductor light emitting stack 20. The first area ratio is a ratio of an area of the plurality of conductive portions 17 overlapping the central portion of semiconductor light emitting stack 20 in the plan view of bottom surface 20a to the area of the central portion of semiconductor light emitting stack 20. The second area ratio is a ratio of an area of the plurality of conductive portions 17 overlapping the peripheral portion of semiconductor light emitting stack 20 in the plan view of bottom surface 20a to the area of the peripheral portion of semiconductor light emitting stack 20.

This can alleviate concentration of carriers at the central portion of semiconductor light emitting stack 20. Even when a high current is injected into semiconductor light emitting device 1, non-radiative recombination of carriers is suppressed, and semiconductor light emitting device 1 has increased luminous efficacy. The drooping effect is suppressed. Semiconductor light emitting device 1 provides an increased optical output when a high current is injected thereto.

Hereinafter, aspects of the present disclosure will be described collectively as additional notes.

### (Additional Note 1)

A semiconductor light emitting device comprising:
a current confinement layer; and
a semiconductor light emitting stack disposed on the current confinement layer and having a bottom surface in contact with the current confinement layer,
the current confinement layer including an insulating layer and a plurality of conductive portions disposed in the insulating layer in contact with the bottom surface,
an area ratio of the plurality of conductive portions to the bottom surface being 7% or more and 15% or less,
the area ratio being a ratio to a first area of the bottom surface of a second area of the plurality of conductive portions overlapping the bottom surface in a plan view of the bottom surface.

### (Additional Note 2)

The semiconductor light emitting device according to Additional Note 1, wherein the plurality of conductive portions are formed of gold.

### (Additional Note 3)

The semiconductor light emitting device according to Additional Note 1 or 2, wherein
the semiconductor light emitting stack includes a p-type contact layer in contact with the plurality of conductive portions, and
the p-type contact layer has a carrier concentration of 1× 10¹⁹ cm⁻³ or more.

### (Additional Note 4)

The semiconductor light emitting device according to Additional Note 3, wherein the p-type contact layer is formed of p-AlGaAsP doped with a p-type dopant.

### (Additional Note 5)

The semiconductor light emitting device according to any one of Additional Notes 1 to 4, further comprising a reflective layer disposed on a surface of the current confinement layer facing away from the semiconductor light emitting stack, wherein the plurality of conductive portions are in contact with the reflective layer.

### (Additional Note 6)

The semiconductor light emitting device according to any one of Additional Notes 1 to 5, wherein the plurality of conductive portions are disposed uniformly in the plan view of the bottom surface.

### (Additional Note 7)

The semiconductor light emitting device according to any one of Additional Notes 1 to 5, wherein
a first area ratio of the plurality of conductive portions at a central portion of the semiconductor light emitting stack is smaller than a second area ratio of the plurality of conductive portions at a peripheral portion of the semiconductor light emitting stack,
the first area ratio is a ratio of an area of the plurality of conductive portions overlapping the central portion of the semiconductor light emitting stack in the plan view of the bottom surface to an area of the central portion of the semiconductor light emitting stack, and
the second area ratio is a ratio of an area of the plurality of conductive portions overlapping the peripheral portion of the semiconductor light emitting stack in the plan view of the bottom surface to an area of the peripheral portion of the semiconductor light emitting stack.

It should be understood that the embodiments disclosed herein are illustrative and non-restrictive in any respect. The scope of the present disclosure is defined by the terms of the claims, rather than the description above, and is intended to encompass any modifications within the meaning and scope equivalent to the terms of the claims.

What is claimed is:

1. A semiconductor light emitting device comprising:
a current confinement layer; and
a semiconductor light emitting stack disposed on the current confinement layer and having a bottom surface in contact with the current confinement layer,
the current confinement layer including an insulating layer and a plurality of conductive portions disposed in the insulating layer in contact with the bottom surface,
an area ratio of the plurality of conductive portions to the bottom surface being 7% or more and 15% or less,
the area ratio being a ratio to a first area of the bottom surface of a second area of the plurality of conductive portions overlapping the bottom surface in a plan view of the bottom surface.

2. The semiconductor light emitting device according to claim 1, wherein the plurality of conductive portions are formed of gold.

3. The semiconductor light emitting device according to claim 1, wherein
the semiconductor light emitting stack includes a p-type contact layer in contact with the plurality of conductive portions, and
the p-type contact layer has a carrier concentration of 1×10¹⁹ cm⁻³ or more.

4. The semiconductor light emitting device according to claim 3, wherein the p-type contact layer is formed of p-AlGaAsP doped with a p-type dopant.

5. The semiconductor light emitting device according to claim 1, further comprising a reflective layer disposed on a surface of the current confinement layer facing away from the semiconductor light emitting stack, wherein the plurality of conductive portions are in contact with the reflective layer.

6. The semiconductor light emitting device according to claim 1, wherein the plurality of conductive portions are disposed uniformly in the plan view of the bottom surface.

7. The semiconductor light emitting device according to claim 1, wherein
a first area ratio of the plurality of conductive portions at a central portion of the semiconductor light emitting stack is smaller than a second area ratio of the plurality of conductive portions at a peripheral portion of the semiconductor light emitting stack,
the first area ratio is a ratio of an area of the plurality of conductive portions overlapping the central portion of the semiconductor light emitting stack in the plan view of the bottom surface to an area of the central portion of the semiconductor light emitting stack, and
the second area ratio is a ratio of an area of the plurality of conductive portions overlapping the peripheral portion of the semiconductor light emitting stack in the plan view of the bottom surface to an area of the peripheral portion of the semiconductor light emitting stack.
